(19) United States
(12) Patent Application Publication
(10) Pub. No.: US 2010/0132990 A1
(43) Pub. Date: Jun. 3, 2010

(54) Device Built By Joining A Plurality Of Layers

(75) Inventors: Erik Peter Veninga, Nuenen (NL); Marinus Marc Koetse, Eindhoven (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Nederlandse Organisatie voor toegepast- natuurwetenschappeliijk Onderzoek TNO, Delft (NL)

(21) Appl. No.: 12/520,494

(22) PCT Filed: Nov. 26, 2007
(86) PCT No.: PCT/NL2007/050597

§ 371 Date: Feb. 22, 2010

(30) Foreign Application Priority Data
Dec. 22, 2006 (EP) 06077309.0

(51) Int. Cl. H05K 1/02; B32B 37/00; B32B 38/00; B32B 3/30; H05K 1/00

(52) U.S. Cl. 174/259; 156/60; 156/153; 428/172; 174/250

(57) ABSTRACT

In a method of manufacturing a multilayer device exposed surfaces of a first and second layer are joined together. Before joining a depression is created in the exposed surface of a layer and raw material, such as electrically conductive material, for forming an electric circuit is deposited in the depression, typically filling the depression. Excess material is mechanically removed before the layers are joined. In this way conductor tracks may be created between layers. When adjacent fluid chambers are provided, separated by one of the layers, the depression with the material in it makes it possible realize a sensor device with a reduced separation between the chambers.

The invention relates to a device built by joining a plurality of layers such as a fluid processing device, for example a microfluidic device and to a method of manufacturing such a device.

US patent application No 2002176804 describes microfluidic devices and their manufacture. Generally microfluidic devices are constructed to process fluids on a small scale. This requires small sized conduits, sensors, valves etc. Microfluidic devices have been manufactured from stacks of polymer layers wherein spatial structures such as grooves in the layer or holes through the layer have been provided. On these layers electrical structures such conductors and resistors have been provided to realize sensors, heater circuits etc. This method of manufacturing significantly reduces material costs. In fact, the majority of the remaining device cost is due to the cost of the manufacturing process, so that it is desirable to reduce the costs of this process.

Once structures have been defined in the layers, the layers are joined to form a device, wherein fluid channels are defined by the holes and the grooves surrounded by material from the layers. Joining is an important step, as it has to ensure leak free and permanent sealing of the channels. Also the method of joining should not damage the structures defined in the layers.

The electrical structures are conventionally defined on the layers by adding electrically active, material on top of the layers. As used herein electrically active materials include materials such as conducting material, semi-conducting materials, resistive materials, piezo electric material or combinations thereof. Electrically active materials may be used to create circuit components such as conductors, resistors, capacitors, actuators, sensing elements etc. in the device “Active” as used herein does not necessarily mean that the material performs an active electronic function, such as amplification etc.

A problem with known microfluidic device manufacture is that the application of electrical material on top of the layers limits the possibilities construction of electrical elements. Moreover many manufacturing steps (e.g.

lithographic patterning steps) are needed when complex devices need to be manufactured. A solution to this problem could also be applied to construction of any electronic circuit, such as the construction of identification cards, such as those used for gates at the entrance of buildings or sensors containing polymeric components, or to shunt bars in flexible organic lighting etc.

US patent application No 2005/0176804 describes a method of joining pieces of a microfluidic device, wherein damage to environmentally sensitive elements in the device is avoided during joining of the layers, by means of localized heating. The document mentions polyelectrolyte and other gels with valving subsystems and electrical sensors as examples of the environmentally sensitive elements. The document shows such an element partly surrounded by a fluid channel extending into two plastic pieces that have been joined to each other. The document does not describe how the elements are placed on the plastic pieces and in particular it does not describe that the elements are created from material that is deposited onto a layer in a depression in the layer. Nor does the document describe that circuits can be structured using the depressions.

Among others it is an object of the invention to provide for a simplification in the manufacture of multi-layer devices such as microfluidic devices.

A method according to claim 1 is provided. Herein electrically conductive, semi-conductive and/or resistive material is provided in a depression of at least one of the layers. This may improve the reliability of joining of the layers when they are forced against each other. Independent of this it makes it possible to reduce feature size and the minimum distance from electrically active material to the opposite surface. This is especially advantageous when the electrically active material has to be provided at close distance between gas compartments on opposite sides of the layers.

These and other objects and advantageous aspects will become apparent from a description of exemplary embodiments using the following figures.

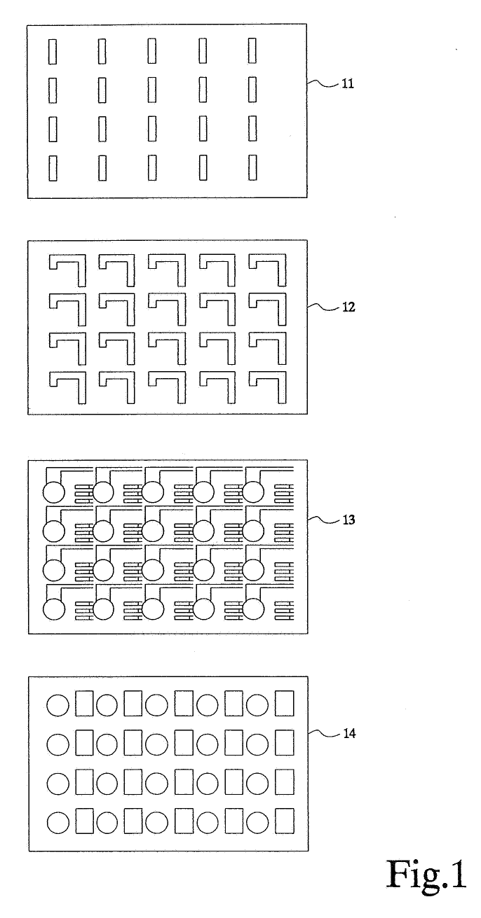

FIG. 1 shows an example of layers used in a microfluidic device

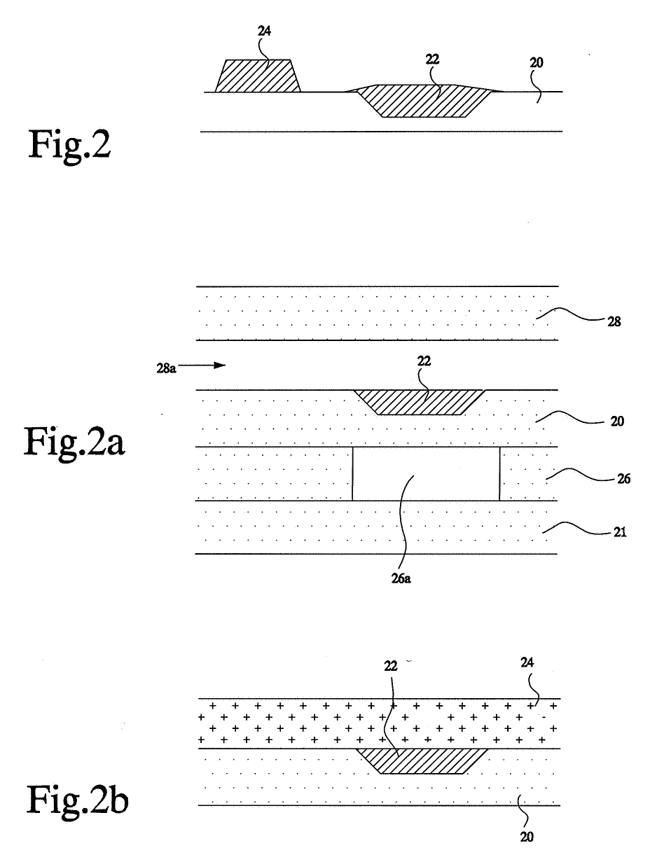

FIG. 2 shows a cross-section of layers used in a microfluidic device

FIGS. 2a-c show multi-layer structures

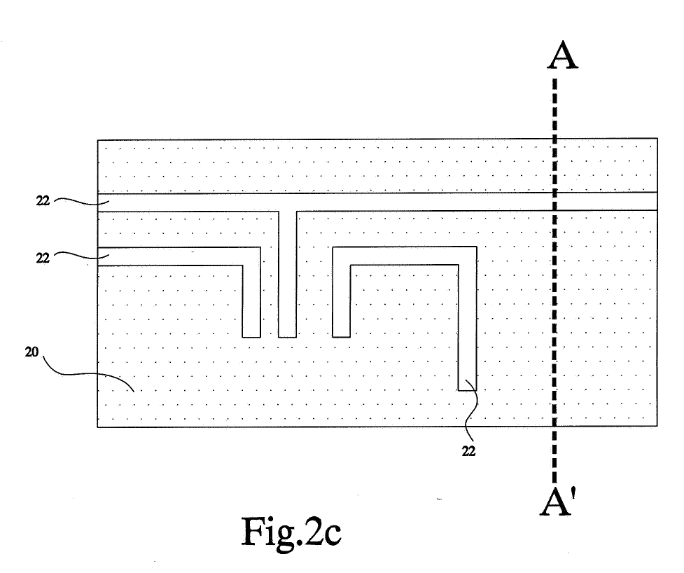

FIG. 3 illustrates an apparatus for joining layers

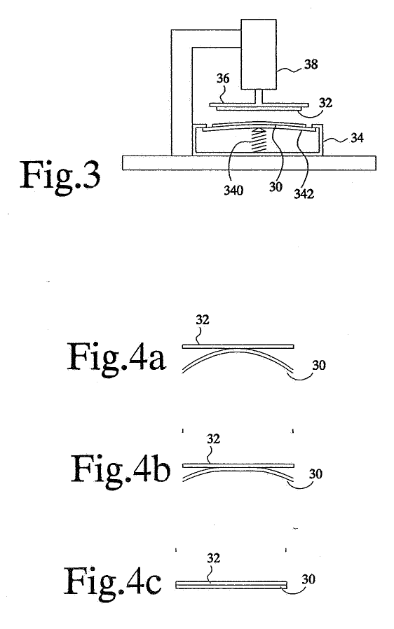

FIGS. 4a-c illustrate layers during a joining process

It is proposed to manufacture gas processing devices as microfluidic devices by defining structures in and/or on layers and subsequently joining the layers. Such a microfluidic device may contain a combination of functional elements such as heaters, valves, flow sensors, flow controllers, mixers and reaction chambers. A chamber or channel is formed by defining a depression in at least one layer and attaching another layer to that layer, closing of the top of the depression. A fluid heater may constructed by providing electrically resistive material in a layer adjacent a channel or chamber. A valve may be constructed for example using a channel adjacent a flexible membrane that borders a chamber containing a gas that can be heated using a heating element. A flow sensor may be constructed for example using a channel adjacent a succession of a temperature sensor (e.g. a temperature dependent resistor, such as a resistor with a positive or negative temperature coefficient) a heater (e.g. a heater resistor) and another temperature sensor. Herein the effect of heating with the heater on temperature can be used as a measure of flow speed. A flow controller can be constructed from a flow sensor along a channel that is coupled in series with a valve, in combination with a feedback loop to control the valve dependent on a difference between measured flow and desired flow. A mixer may be constructed from a plurality of flow controllers with outputs coupled to a common channel or chamber.

Such devices can be realized by defining grooves in layers, to serve as channels or chambers, by providing layers to serve as flexible membranes and providing layers with electrical elements such as resistances, temperature dependent resistances, connecting wiring etc. and joining such layers. As used herein resistances are elements with a resistivity that is at least so low that it allows functionally significant currents to flow, i.e. currents that will be measured in operation, used to define bias voltages or currents or used to create a physical effect such as heating. The term resistive material has a similar meaning. A matrix of repeating patterns of structures can be defined on the layers and after stacking the layers by joining the stack can be partitioned into devices. A number of functional elements, in fluidic contact with each other via channels may be realized within each device.

FIG. 1 illustrates layers used during manufacture of a microfluidic device. The main surface of the layers (top view) is illustrated. In a first layer 11 a matrix of grooves 110 is constructed, for example by milling, cutting, moulding, laser ablation, embossing, etching or the like. Within each groove a hole through the layer may be constructed with a similar technique. A second layer 12 comprises a matrix of grooves and holes with a different shape, which can be manufactured in a similar way. During manufacture second layer 12 will be joined to first layer 11, so that the holes in the second layer 12 connect the grooves in the second layer to the grooves in the first layer. On a third layer 13 a number of matrixes of electrical elements is deposited, such as for example a matrix of temperature dependent resistances, heater resistances, and conductors. During manufacture third layer 13 will be joined to second layer 12. In a fourth layer 14 holes are defined to serve as chambers for gas for example, or as vias for electrical connections. During manufacture fourth layer 14 will be joined to third layer 13. A fifth layer (not shown) serves as cap for the chambers and contains holes as via's for connections. During manufacture the fifth layer will be joined to fourth layer 14.

In this example of the microfluidic device the device contains a combination of a valve and a gas flow sensor manufactured by stacking a plurality of layers, wherein the conduit for the valve and the conduit for the gas flow sensor are defined by a same layer, and wherein a heating element and a temperature sensor for the gas flow sensor are printed on the flexible layer that provides the flexible wall of the chamber of the valve.

By using the flexible layer both as a flexible layer for the valve and as a base for the heater and sensor, the number of steps in the manufacture of the device can be reduced. As described, preferably, the heating element of the valve is also printed in and/or on the flexible layer. Alternatively different layers with electrical elements may be used, for example in order to realize more complex devices or to speed up manufacturing.

The layers can be of polymer material, such as P (polyimide), PET (Polyethylene terephthalate), PC (Polycarbonate), PEEK (Polyetheretherketone), PMMA (Polymethylmethaacrylate), PEN (Polyethylene Nqqq) etc.

The layers need not all be of the same material. A layer that defines flexible membranes may be thinner for example and/or made of a different material.

FIG. 2 illustrates an embodiment of a layer 20 with electrical structures (not to scale). In this embodiment depressions are defined in the layer 20 and electrically resistive material 22 (e.g. a compound containing electrically resistive particles) is deposited in the depressions. Alternatively, or in addition, structures 24 containing such material may be defined on a flat layer portion, for example by printing or by photolithographic etching. Instead of resistive material, other electrically active material may be deposited, such as conductive material or semi-conductor material or mixtures thereof.

The advantage of using depressions is that thinned portions of the layer can be defined for example to provide more flexibility in a resilient wall of a compartment such as a chamber, or to provide for a faster reaction to heating by a heater in the depression or faster sensing of temperature changes. Another advantage is that the depressions serve as an ‘embedded’ mask or stencil for the printing of the material 22. This method enables the creation of finer structures (e.g. with structures with widths smaller than 100 um) than conventional printing techniques (which are limited to structures of at least 100 um). The depressions can be realized by any convenient method, such as local etching, milling laser ablation, embossing or moulding techniques etc. The depressions may be for example half as deep as the layer is thick or even deeper to provide for close proximity to the opposite face of the layers (of course if less proximity suffices less deep depressions may be used). Depressions of 20 micron deep in 30 micron thick layers may be used for example. Use of depressions has the advantage that smaller features can be defined and that the distance between the electrically active material and the furthest surface of the layers can be increased. In addition, less electrically active material extends above the surface, thus reducing problems such as trapping of gas when the layers are joined.

FIG. 2a shows a cross-section of a multilayer structure with compartments 26a, 28a. and inbetween these compartments a layer 20 with a depression wherein electrically active material has been deposited. The multilayer structure comprises a first layer 21, a second layer 26, a third layer 20 and a fourth layer 28. Second layer 26 is provided on top of first layer 21 and third layer 20 is provided on top of second layer. An opening is provided in second layer 26, which defines a compartment (or chamber) 26a that is at least partly confined by first, second and third layer 21, 26, 22. Fourth layer 28 is provided on top of an intermediate layer (not shown), which intermediate layer is provided on top of third layer 20. In the intermediate layer an opening has been provided that defines a compartment (or channel) that is at least partly confined by Fourth layer 28, third layer 20 and the intermediate layer (not shown). The intermediate layer (not shown) makes up side walls of the channel in fron and behind the plane of the cross-section through the multilayer structure. A depression has been made in first layer 20 and in this depression electrically active material 22 has been deposited. The depression with the material is provided between the compartments 26a, 28a (the channel and chamber). It may be noted, that “between” does not mean that the depression should extend at least over the entire overlap of the compartments, or vice versa that the overlap should extend at least over the entire depression. It suffices that there are points of overlap between the compartments between which the depression is provided.

FIG. 2b shows a cross-section of a multilayer structure wherein a first layer 20 and a second layer 24 are provided attached to each other. A depression filled with electrically active material is provided in first layer 20 in its surface that faces second layer 24. More layers (not shown) may be present on either side. Such layers may contain channels for fluid flow etc.

FIG. 2c shows a top view of a a multilayer structure of FIG. 2b. The cross-section FIG. 2b is indicated by the line A-A′. As shown, a plurality of depressions with electrically active material 22 may be provided, running along routes that define electrical current paths that run parallel to the surface of first layer 20.

The layers may be polymer foils. Although an example is shown with a depression in a single layer, that is, without reaching through the layer, it should be appreciated that the depression may be a depression in a stack of layers, in which case it may extend though more than one layer in the stack.

The material that is deposited in the depression is an electrically active material. As used herein an electrically active material means a material from which structures of an electrical circuit may be formed in the multilayer device. The structures formed from the electrically active material may be circuit components such as conductors, resistors, capacitors, actuators, sensing elements etc. Examples of electrically active materials include materials such as conducting material, semi-conducting materials, resistive materials, piezo electric material or combinations thereof. Typically, the material is homogeneous, in the sense that its composition does not change in any functionally significant way as a function of position in the depression.

The electrically active material is preferably deposited in a state in which it can still be shaped, so that the material takes on the shape of the depression in which the material is deposited, as far as the material is brought into contact with the wall of the depression. In an embodiment the entire cross-section of the depression is filled with the material, as shown in FIG. 2. In an alternative embodiment the amount of material may be selected so that the cross-section of the depression is only partly filled. Examples of material states that allow shaping are materials in the state of a paste or in the liquid state, wherein there is only a surmountable viscous resistance against reshaping a quantity of material. After deposition the material may be cured so that it can no longer be reshaped.

The depressions may be used to provide electrical interconnections for routing electric currents in directions that are parallel to the layers. Thus, for example, currents may be supplied to various terminals of an integrated circuit, transistor coil etc. that is provided on a layer, to connect to a via through a layer at a specific position in the layer or between terminals in any other electric circuit, such as terminals that are accessible outside the device and/or terminals of discrete components of the electric circuit.

When such an electrical interconnection for routing an electrical current is to be provided, a depression is created in the surface of a layer, extending along the intended route of the interconnection. The route may extend along a line for example, the depression having a width transverse to the line that is substantially less than its length and sufficient to define an interconnection track. The route may comprise a plurality rout parts along such lines on the surface of a layer, in contact with each other and at non-zero angles with respect to each other, or rout parts that split at T junctions. A plurality of mutually separate routes may be realized in this way on the same layer. Subsequently, electrically active material such as conductive material is deposited in the depression to form the electrical interconnection. When the conductive material serves as an outside terminal, part of the layer with the depression may be left uncovered by any other layer, leaving part of the depression uncovered to facilitate access.

The electrically active material may be deposited in various ways. In one embodiment the material is first applied to a layer that has depressions thereon, and subsequently spread over the layer and/or removed from areas on the layer where there are no depressions, and/or from a positions over a depression that extends from the depression beyond the level of the surface of the layer, using a squeegee, i.e. with a blade and/or roller. Thus the material outside the depression is mechanically moved off the layer in a lateral direction along the surface of the layer, by scraping or pushing off the surface of the layer. The material may be first applied to the layer for example by pouring the material onto the surface of the layer in liquid form, or applying it in paste form to the whole or part of the surface. In an embodiment printing techniques may be used such as inkjet or bubble-jet printing, offset printing etc. using the electrically active material instead of ink. In this embodiment the material may be applied selectively to the locations where depressions are provided in the surface of the layer.

Optionally a subsequent step may be performed wherein a squeegee, or other mechanical moving device, is used to mechanically remove any excess and/or material that has been deposited outside the depressions. Such removed excess material may be material that extends from the depression above the level of the surface of the layer. The deposited material may then be cured to solidify the material. Curing may be done by heating, or UV irradiation etc., dependent on the material. In an alternative embodiment, the material may be left uncured, e.g. in a viscously deformable state. This is possible for example when the material is confined between the layers, so that the material cannot be deformed because the material is confined rather than because it is intrinsically not deformable.

It should be noted that after assembly of the layers, along at least part of the route of the interconnections the space between the layers in the depression may be entirely filled, leaving no open space for fluid flow. That is, the depressions need not act as fluid conduits in a micro-fluidic device.

A depression with electrically active material adjacent walls of chambers may be provided in combination with such electrical interconnections, connected to the interconnections for example, or on its own, without combining it with electrical interconnections in depressions. Similarly, electrical interconnections may be used without using depressions adjacent walls of chambers.

This technique is particularly well suited for providing electrical interconnections in foil layers, made up of polymers, as it allows for a simple method of realizing interconnections that is suitable for foils and allows for small scale circuit structures.

FIG. 3 illustrates an apparatus for joining layers 30, 32. It should be emphasized that this apparatus is shown merely by way of example. Any known method of joining may be used to join layers 30, 32. The apparatus comprises a first holding assembly 34, a second holding assembly 36 and an actuator 38. Second holding assembly 36 is attached to actuator 38. First holding assembly 34 comprises a resilient element 340, such as a spring, a piston etc and an elastically deformable table 342.

In operation, first holding assembly 34 serves to hold a first layer 30 of a multilayer device. Second holding assembly 36 serves to hold a second layer 32, so that surfaces of the first and second layer 30, 32 face each other. Although a description will be given in terms of single layers it should be understood that the description also applies if a stack of layers is used instead of single layers; also it should be understood that the first and second layer in FIG. 3 can be any of the layers described in the preceding or another layer.

An adhesive is applied to at least one of the facing surfaces. Suitable adhesives for joining layers are known per se. In a embodiment the adhesive is applied by first applying the adhesive to an auxiliary surface (not shown) and subsequently pushing second holding assembly 36 with second layer 32 thereon against the auxiliary surface. In a further embodiment second layer 32 contains deepened structures such as channels. In this further embodiment this method of applying adhesive ensures that no adhesive is applied in the structures. However, alternatively other techniques of applying adhesives may be used.

First layer 30 is held on elastically deformable table 342. In an embodiment first layer 30 is held by suction force. In a first further embodiment holes (not shown) are provided in elastically deformable table 342 and a pump (not shown) is coupled to a chamber underneath elastically deformable table 342. Above first layer a gas pressure higher than the pressure in the chamber is maintained. In an alternative embodiment elastically deformable table 342 comprises a top layer with holes provided on top of a layer with grooves from a perimeter of elastically deformable table 342 to the holes. In this embodiment the perimeter is coupled to a pump not shown. Thus, no surface on first layer 30 need be sacrificed for holding first layer 10. It should be appreciated that this method of holding first layer 30 is useful only if no vacuum is required in the space between first layer 30 and second layer 32. As an alternative other methods of holding first layer may be used, such as mechanical attachment, temporary gluing, holding by gravity etc.

Second layer 32 is held on a rigid table on second holding assembly. 36. In an embodiment second layer 32 is held by suction force. A similar construction for holding may be used as in first holding assembly 34.

First and second layer 30, 32 are aligned with each other, so that the location of corresponding structures on the layers coincide. Alignment may be performed for example by measuring the position of structures or reference marks on the layers 30, 32 when attached to first and second holding assemblies 34, 36 and displacing the first and second holding assemblies 34, 36 relative to each other until the measurements indicate alignment.

Resilient element 340 exerts a force on a central region of elastically deformable table 342 in a direction of second layer 32. The central region may be point shaped or line-shaped (e.g. along a diameter of elastically deformable table 342. Away from the central region edges of elastically deformable table 342 are attached to (or at least withheld by) withholding elements (e.g. projections) of first holding assembly 34 that act in a direction opposite the direction of the force exerted by resilient element 340. Resilient element 340 is constructed so that the force is sufficient to deform the combination of first layer 30 and elastically deformable table 342. As a result the combination of first layer 30 and elastically deformable table 342 is deformed so that it acquires a curved surface with a central point, or line closest to second layer 32.

Initially the facing surfaces of the layers 30, 32 are spatially separated from one another. Subsequently actuator 340 moves second holding assembly 16 towards first holding assembly 34. As a result the surface of second layer 32 first comes into contact with the surface of first layer 30 at its central point or line. Subsequently actuator 340 gradually moves second holding assembly 36 further towards first holding assembly 34. As a result of the movement the deformation is gradually pushed out of first surface 30 and an increasingly larger part of second layer 32 comes into contact with the surface of first layer 30.

FIGS. 4a-c illustrate the layers during contact, with exaggerated deformation. FIG. 4a shows the layers at initial contact. FIG. 4b shows the layers after further relative movement of the layers. FIG. 4c shows the layers after yet further relative movement of the layers.

As will be appreciated the apparatus provides for an arbitrarily controllable speed of expanding the area wherein the surfaces of the layers 30, 32 are in contact. Further movement of the second layer towards the first layer results in increasing contact area. Thus, the speed can be selected sufficiently slowly to prevent trapping of gas bubbles between the layers.

Although a specific embodiment of the apparatus has been schematically illustrated, it should be appreciated that alternative constructions are possible. As an example, instead of a combination of resiliently deformable table 342 and a resilient element 340, a pre-deformed resiliently deformable table may be used, which assumes a curved shape when no force is exerted and is flattened when a force is exerted, or such a curved shape may be realized by pre-tensioning the resiliently deformable table 342 in first holding assembly 34.

As another example, although an embodiment has been discussed wherein the second layer 32 is held on a rigid table, it should be understood that alternatively second layer 32 could be held on a resiliently deformed table as well, or could even be held self-supporting without a table, except for a position where force is exerted on the first layer 30 to deform the first layer. If the first layer 30 is sufficiently resilient, it may also be held without supporting table a bending of the first layer itself being deformed under influence of the force.

As another example, instead of movement of second layer 32 other forms of relative movement of the layers 30, 32, such as movement of first layer 30 may be used. As another example, instead of a gradual movement of first and second layer 30, 32 towards each other, a controlled temporally increasing force may be used for compressing the layers.

As another example, a non-resilient support of the centre of first layer 30 could be used in combination with a resilient connecting structure between the edges of first layer 30 and second layer 32. In general, to enable deformation, a resilient force should act between a support area where the resilient element 340 or the support supports first layer 30 and withholding areas on the first layer 30 on mutually opposites of the support area.

The shape and location of the support area can be selected dependent on the application. In an embodiment a point shaped, or circular support area in the centre of the layer may be used. In this case the edge of the contact between the layers typically propagates as a circle with increasing radius. Alternatively, a line shaped area extending along the length of the layer may be used. In this case the edges of the contact area between the layers typically propagate from the support area in the form of parallel lines. In another embodiment off centre support may be used.

Although an embodiment of the invention in microfluidic devices has been illustrated, it should be appreciated that deposition of electrically active material in a depression in the surface of a layer, followed by joining of the surface of the layer to another layer, could be used in the manufacture of other types of device as well. For example, in an electronic identification card, a circuit component may be realized in this way, by a similar manufacturing technique. As another example, a sensor comprising polymeric components may be improved by using this technique. WO2005015173 describes this type of sensor per se. As a further example, the technique may be applied to the manufacture of circuits in flexible electronics, such as flexible organic light sources etc.

1. A method of manufacturing a multilayer device, the method comprising:
providing a first layer or stack of layers having an exposed surface;
providing a second layer or stack of layers having an exposed surface;
creating a depression in said exposed surface of the first layer or stack of layers;
depositing electrically active material onto the first layer or stack of layers in the depression, an electrical component being created from the electrically active material in the device; and
joining the exposed surfaces of the first layer or stack of layers and second layer or stack of layers after the electrically active material has been deposited.

2. A method according to claim 1, wherein a cross-section of the depression is entirely filled with the electrically active material.

3. A method according to claim 1, wherein the electrically active material is deposited in a material state that allows the electrically active material to take on a shape of the depression where the electrically active material is deposited in contact with the first layer or stack of layers in the depression.

4. A method according to claim 1, wherein an excess portion of the electrically active material is moved laterally along the surface of the first layer or set of layers after depositing the material, leaving the electrically active material in the depression.

5. A method according to claim 1, comprising defining a pair of fluid compartments in the device, the fluid compartments abutting at mutually opposite sides to the first layer or a layer from the first stack of layers wherein the depression has been created with the electrically active material in the depression, the depression and the electrically active material in the depression lying between the fluid compartments, when the device has been assembled.

6. A method according to claim 1, wherein the active material in the depression forms an electrical interconnection for routing electrical current in an electric circuit in the device, along a route that is parallel to the surface of the first layer or stack of layers, a course of the depression defining a course of the route.

7. A method according to claim 1, comprising creating the depression by removing material from the first layer or stack of layers.

8. A method according to claim 7, comprising creating the depression by mechanical removal of material from the first layer or stack of layers.

9. A method according to claim 7, comprising creating the depression by removal the material from the first layer or stack of layers using laser ablation or etching.

10. A method according to claim 1, comprising embossing the first layer or stack of layers to form the depression.

11. A method according to claim 1, wherein the first layer or stack of layers comprises a polymer foil, the depression being created in the polymer foil.

12. A multilayer device comprising a stack of joined layers, the stack of joined layers comprising a layer wherein electrically active material is present that has been deposited onto the layer in a depression of the layer that faces another layer of the stack layers.

13. A multilayer device according to claim 12, wherein the layer is attached to the other layer by glue.

14. A multilayer device according to claim 12, comprising a pair of fluid compartments abutting to mutually opposite sides to the first layer or a layer from the first stack of layers wherein the depression has been created with the electrically active material in the depression, the depression and the electrically active material in the depression lying between the fluid compartments.

15. A multilayer device according to claim 12, comprising an electric circuit comprising an electrical interconnection for routing electric current between parts of the electric circuit along a route that is parallel to the surface of the layer, the electrically active material forming the electrical interconnection, the depression defining a course of the route.

16. A multilayer device according to claim 13, comprising an electric circuit comprising an electrical interconnection for routing electric current between parts of the electric circuit along a route that is parallel to the surface of the layer, the electrically active material forming the electrical interconnection, the depression defining a course of the route.

17. A multilayer device according to claim 13, comprising a pair of fluid compartments abutting to mutually opposite sides to the first layer or a layer from the first stack of layers wherein the depression has been created with the electrically active material in the depression, the depression and the electrically active material in the depression lying between the fluid compartments.
